(19) United States
(12) Patent Application Publication
(10) Pub. No.: US 2004/0057312 A1
(43) Pub. Date: Mar. 25, 2004

(54) Method for operating an IC with a memory array

(76) Inventor: Raj Kumar Jain, Singapore (SG)

Correspondence Address: HORIZON IP PTE LTD, 166 Kallang Way, 6th Floor, SINGAPORE 349249, SG

(21) Appl. No.: 10/065,211

(22) Filed: Sep. 25, 2002

(51) Int. Cl. G11C 7/00

(52) U.S. Cl. 365/205

(57) ABSTRACT

A memory array includes sense amplifiers with a portion for amplifying a low level signal and a portion for amplifying a high level signal on bitlines. In an improved method for operating the memory array, the first portion of the sense amplifier is enabled before the second portion of the sense amplifier. The two-step amplification process reduces noise injection and lowers peak current consumption during the sense operation.

### BACKGROUND OF INVENTION

Integrated circuits having an array of memory cells such as dynamic random access memory (DRAM) cells, store information in the form of a charge in a storage capacitor. A dynamic random access memory (DRAM) cell comprises a storage capacitor and a selection transistor. A plurality of memory cells is interconnected by wordlines and bitlines to form an array. In order to access a memory cell, a wordline is activated to make the selection transistor conductive. The charge in the storage capacitor is output onto a bitline. The relatively small charge from the storage capacitor introduces a differential voltage on the bitline which is sensed by a sense amplifier and amplified to a full level signal. The amplified signal is forwarded to the data read path. In case of a write access, a signal is received from a write path.

To facilitate memory accesses, sense amplifiers are used. A sense amplifier is coupled to two bitlines. Before an access to a memory cell, the bitlines connected to a particular sense amplifier are equalized and are forced to a predetermined precharge potential (e.g., V_{DD}/2). Prior to activating the wordline, the precharge potential source is disconnected from the bitlines and the equalization between the bitlines is opened. Then, the charge stored in the storage capacitor of the memory cell is connected to one of the two bitlines by activating the wordline and outputs its relatively small charge onto that bitline. Since the bitline capacitance is considerably larger than the capacitance of the memory capacitor, the charge from the storage capacitor placed onto the bitline results in a very small potential shift on that bitline. The potential shift is either positive or negative relative to the precharge potential and is indicative of the information stored in the memory cell.

The signals on the bitlines are then amplified to their different full potentials. The value (positive or negative compared to the precharge potential) of the amplification on the bitline connected to the memory cell is dependent on the value of the charge received from the storage capacitor. Since the potential shift on the bitlines caused by the charge from the storage capacitor is relatively small, the sensing and amplification operation is very sensitive to noise. This can cause errors in the sensing operation.

From the above discussion, it is desirable to provide a sense amplifier which improves the sensing window.

### SUMMARY OF INVENTION

The invention relates to ICs with a memory array. More particularly, the invention relates to improving the sensing window for reading information from the memory array. In one embodiment, the amplification operation for the high level signal and the low level signal are not started simultaneously. In one embodiment, the amplification for the low level signal is started first while the amplification operation for the high level signal remains idle. When the signal distance between the low level signal and the high level signal has increased, the amplification operation for the high level signal begins. The noise margin is thereby increased. In particular, this operational feature is preferably achieved by enabling the portion of the sense amplifier which is responsible for the amplification of the low level signal, and subsequently enabling the portion of the sense amplifier which is responsible for the high signal amplification. As an additional advantage, the peak current consumption of the sense amplifier is reduced so that the circuits providing the current can be less complex in design and the introduction of switching noise is reduced so that the sensing and amplification operations are more reliable.

### BRIEF DESCRIPTION OF DRAWINGS

FIG. 1 shows a block diagram of a memory device in accordance with one embodiment of the invention;

FIG. 2 shows a memory cell in accordance with one embodiment of the invention;

FIG. 3 shows a sense amplifier in accordance with one embodiment of the invention;

FIG. 4 shows a timing diagram for operating a memory device in accordance with one embodiment of the invention;

FIG. 5 shows the waveforms for various control signals, according to one embodiment of the invention;

FIG. 6 shows the general sequence of control signals in accordance with one embodiment of the invention; and

FIG. 7 shows the flow of control signals in accordance with one embodiment of the invention.

### DETAILED DESCRIPTION

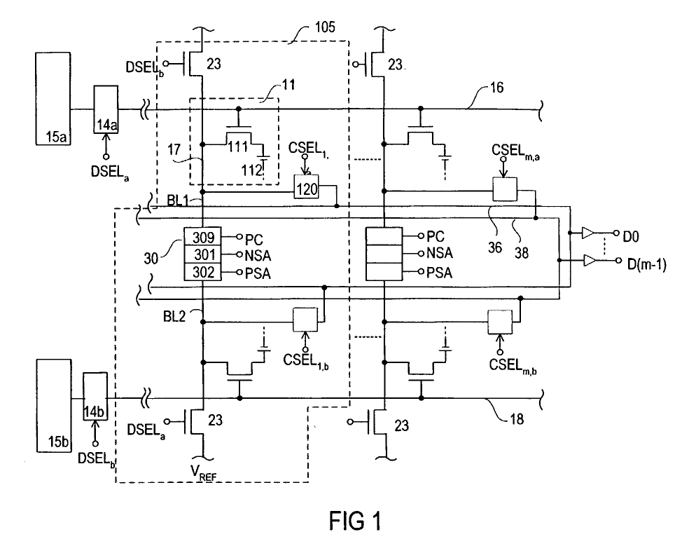

FIG. 1 shows a memory array having a plurality of memory cells 11. The memory cells, for example, are dynamic random access memory (DRAM) cells. A DRAM cell includes a cell transistor 111 coupled to a cell capacitor 112. The storage capacitor carries a charge indicative of the information stored. The cell transistor includes a gate and first and second terminals. One terminal of the transistor is coupled to a terminal of the capacitor while the other terminal is coupled to a bitline 17. The gate is coupled to a wordline 16. The other terminal of the capacitor is coupled to, for example, a reference voltage, such as V_{DD}/2. Other types of memory cells, such as static or multi-port cells, are also useful.

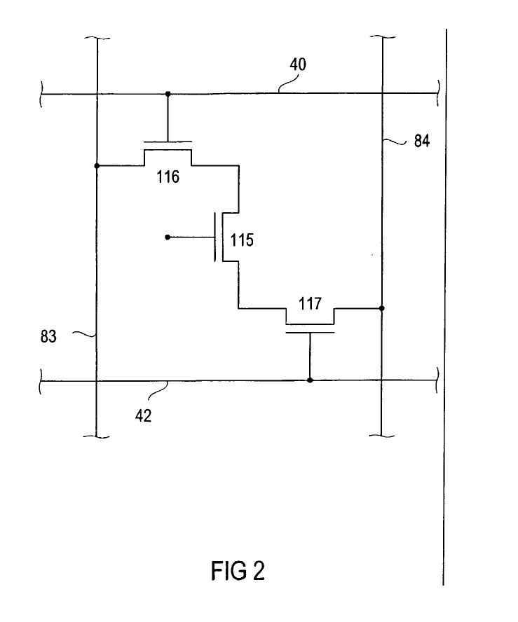

FIG. 2 shows a memory cell in accordance with another embodiment of the invention. Such a memory cell is described in, for example, co-pending patent application, titled “Memory Architecture with Refresh and Sense Amplifiers”, U.S. Ser. No. 09/855,147 (attorney docket number: 00P19334US), which is herein incorporated by reference for all purposes. The memory cell comprises a storage transistor 115. The gate electrode of the storage transistor 115 is connected to a reference potential, e.g. the positive power supply V_{DD}. One end of the drain source path of storage transistor 115 is connected to a selection transistor 116, the gate of which being connected to wordline 40 and another end of its drain source path being connected to bitline 83. The other end of the drain source path of storage transistor 115 is connected to a second selection transistor 117, the gate of which is being connected to wordline 42 and another end of its drain source path being connected to bitline 84. As shown, the transistors of the memory cell are n-channel-MOS-transistors. Providing p-channel-MOS-transistors or a combination of p and n-channel-MOS transistors is also useful. In an alternative embodiment, the storage transistor 115 is replaced by a storage capacitor.

Referring back to FIG. 1, the memory cells are arranged in a plurality of columns 105, where a column comprises first and second bitlines (BL1 and BL2) coupled to a sense amplifier 30. Illustratively, the bitlines are arranged in an open bitline architecture. In an open bitline architecture, the bitlines of a column are located on different sides of the sense amplifier (e.g., not adjacent to each other). Other types of architectures, such as folded or open-folded, are also useful. For purposes of discussion, the bitlines are depicted with only two columns of memory cells interconnected by wordlines 16 and 18. It is understood that a plurality of such memory cells are coupled to both the first and second bitlines of the array, interconnected by respective wordlines to form a plurality of rows. The wordlines are coupled to a wordline decoder 15. The wordline decoder selects one of the wordlines of the bitline pair based on the row portion of the address. In one embodiment, a row selection circuit 14 is activated to couple the selected wordline to a wordline driver. This is achieved with, for example, a decoder select signal DSEL_{a-b}. The subscript represents, for example, the respective memory blocks “a” or “b”. The selection circuit, for example, comprises a transistor. Alternatively, other types of selection circuits can also be used. The selection circuit can also be incorporated in the wordline decoder.

In one embodiment, a column selection circuit 120 is provided for each bitline. The column selection circuit selectively couples a bitline to the data line. In one embodiment, the column selection circuits couple a first bitline BL1 and a second bitline BL2 to a data line 36. The column selection circuit is controlled by, in one embodiment, a column select signal CSEL_{(1-m),(a-b)}. For example, an active CSEL_{m,a} selects the bitlines corresponding to the m-th word within a row, in memory block a. The CSEL signal is generated by, for example, the column decoder. In one embodiment, a column selection circuit comprises a transmission gate.

In one embodiment, dummy cells (not shown) are provided for each bitline. The dummy cells are used to provide symmetrical capacitances to the two bitlines of a column. For example, during a memory access, a memory cell is selected from one of the bitlines of the column while the dummy cell is selected from the other bitline. In one embodiment, the potential of the dummy cell is the precharge level V_{REF}. Providing other potentials for the dummy cell is also useful. In one embodiment, a transistor 23 is provided to selectively couple the dummy cell to the non-selected bitline (e.g., the bitline to which the selected memory cell is not coupled) of a column. In one embodiment, the transistor is controlled by the row decoder (e.g., DSEL signal).

During a memory access, such as a read, an address corresponding to the memory cell to be accessed is provided. The sense amplifier precharges the bitlines to a precharge level V_{REF}. In one embodiment, V_{REF} is equal to about V_{DD}/2. Other values of V_{REF} are also useful. The row portion of the address is decoded by the wordline decoder. Based on the decoded row address, a wordline is selected or activated. For example, wordline 16 is activated. The selected wordline is driven to an active voltage level (e.g. logic 1) by a wordline driver. As a result, a memory cell coupled to the selected wordline is coupled to its respective bitline (e.g. BL1). In one embodiment, dummy cells are coupled to BL2 (e.g., non-selected bitlines). The non-selected bitlines serve as reference bitlines.

The charge in the capacitor of the selected memory cell causes a differential read signal on the pair of bitlines in a column. The value of the differential voltage depends on the information stored in the selected memory cell. For example, if a logic 1 is stored, the differential voltage will be positive with respect to the reference bitline voltage. Conversely, when a negative differential voltage is produced, a logic 0 is stored. The sense amplifier of the column amplifies the differential signal to be read out from the memory cell. One of the selection circuits is activated based on the decoded column address. The activated column selection circuit couples its respective bitline to the data line.

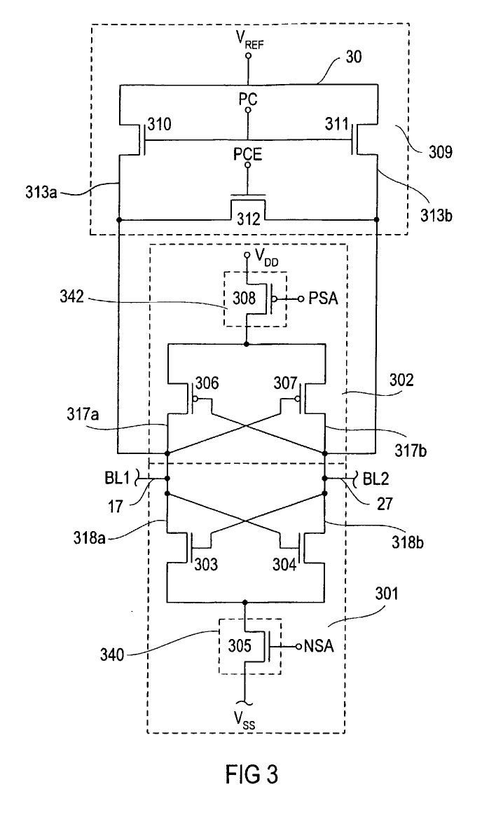

FIG. 3 shows a sense amplifier in accordance with one embodiment of the invention. As shown, the sense amplifier includes a precharge portion 309, an n-channel-transistor portion 301, and p-channel-transistor portion 302.

The precharge portion is used to precharge the bitlines of the column to V_{REF}. In one embodiment, the precharge portion comprises first and second paths 313a-b coupled to V_{REF} and the first and second bitlines BL1 and BL2 of the column. First and second transistors 310 and 311 are coupled in series with the first and second paths, respectively. In one embodiment, the transistors are n-channel-transistors. Employing p-channel-transistors or a combination of n- and p-channel-transistors is also useful. The transistors are controlled by the precharge signal (PC). An active PC signal couples V_{REF} to the bitlines, causing the bitlines to be driven to V_{REF}. The active PC signal, for example, is a logic 1 signal. If p-channel-transistors are employed, providing an active PC signal which is logic 0 is also useful.

In one embodiment, the first and second paths are coupled by an equalization transistor 312. The equalization transistor is coupled to the first and second paths between the first and second transistors and bitlines. The equalization transistor is controlled by, for example, a precharge equalization (PCE) signal. When an active PCE signal is provided, the first and second paths are coupled. This ensures that both bitlines are equalized. The full logic 1 voltage level is equal to about V_{DD} and the logic 0 level is equal to about V_{SS}. In one embodiment, V_{REF} is equal to V_{DD}/2. Alternatively, V_{REF} is equal to V_{SS} for ground level sensing. Other voltage levels for V_{REF} are also useful. Preferably, V_{REF} is equal to about V_{DD}/2+Δ V, where Δ V is equal to an offset voltage. The offset voltage can be positive or negative to compensate for body effect and/or the voltage drop across the cell transistor. The offset voltage is generated by, for example, a charge pump.

The n-channel-transistor portion is coupled to the bitlines for amplifying either BL1 or BL2 to a logic 0 level, depending on the value of the differential read signal. For example, if the differential read signal is positive, the reference bitline is amplified to a logic 0 voltage level by the n-channel-transistor portion. Otherwise, the selected bitline is driven to a logic 0 voltage level. In one embodiment, the n-channel-transistor portion comprises first and second paths, 318a-b. The first and second paths are coupled to a logic 0 voltage source and first and second bitlines. The logic 0 voltage source, for example, is equal to V_{SS} or ground. In one embodiment, the first and second paths comprise first and second transistors (303 and 304). The transistors are n-channel transistors which are cross-coupled.

An n-select circuit 340 is located between the voltage source and the first and second paths. To activate the n-channel transistor portion, an active control signal (NSA) is provided to the n-select circuit. The active NSA signal is, for example, a logic 1 signal. In one embodiment, the n-select circuit comprises an n-FET. If a p-channel-transistor is employed, providing an active NSA signal which is logic 0 is also useful. When an active NSA signal is provided, the appropriate bitline (e.g., bitline with signal having smaller magnitude with respect to the other bitline) of the bitline pair is amplified to the full logic 0 level.

The p-channel-transistor portion is coupled to the bitlines for amplifying either BL1 or BL2 to a logic 1 level, depending on the value of the differential read signal. For example, if the differential read signal is positive, the selected bitline is amplified to a logic 1 voltage level by the p-channel-transistor portion. Otherwise, the reference bitline is driven to a logic 1 voltage level. In one embodiment, the p-channel-transistor portion comprises first and second paths 317a-b. The first and second paths are coupled in series with the first and second paths of the n-channel-transistor portion. The other end of the first and second paths are coupled to a logic 1 voltage source (e.g., V_{DD}). In one embodiment, the first and second paths comprise first and second transistors. In one embodiment, the transistors are p-FETs which are cross-coupled.

A p-select circuit 342 is located between the voltage source and first and second paths. To activate the p-channel transistor portion, an active control signal (PSA) is provided to the p-select circuit. The active PSA signal is, for example, a logic 0 signal. In one embodiment, the p-select circuit comprises a p-FET. Providing a logic 1 active PSA signal is also useful if an n-channel-transistor is employed. When an active PSA signal is provided, the appropriate bitline of the bitline pair is amplified to the full logic 1 level.

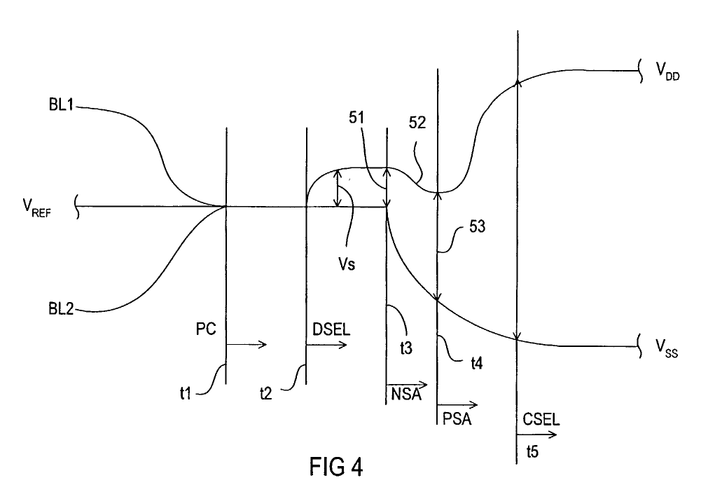

FIG. 4 shows the differential read signal on the bitlines of a column in accordance with one embodiment of the invention. As shown, at t1, the bitlines BL1 and BL2 are precharged or equalized to V_{REF} in preparation for a read access. After the bitlines are equalized, the DSEL signal is activated to drive the selected wordline to, for example, a logic 1. The charge contained in the capacitor of the selected memory cell causes the voltage level on the selected bitline to either a positive or negative voltage with respect to V_{REF}, creating a differential voltage having a magnitude equal to Vs. As shown, the selected bitline is positive with respect to V_{REF}. The reference bitline remains at V_{REF}.

In one embodiment, an active NSA signal is provided at t3. The active NSA signal causes the sense amplifier to charge the bitline having the lower voltage level to a logic 0 level. In this case, the reference bitline is charged to a logic 0 level. The coupling of the bitlines causes the selected bitline to be pulled lower along with the reference bitline. The magnitude of the differential voltage between the bitlines is increased.

In accordance with one embodiment of the invention, an active PSA signal is provided at t4 to charge the selected bitline to the full logic 1 or V_{DD} level. By delaying the activation of the PSA signal, the difference between the voltages on the selected and reference bitlines is larger than between t2 and t3. The larger difference increases the sensing window, improving sensing performance. In one embodiment, the activation of the PSA signal is delayed to increase the differential signal. Preferably the delay increases the sensing window while still permitting signals on the bitlines to be amplified sufficiently to the full voltage levels prior to pulling the signal out onto the data line. At t5, an active CSEL signal causes the signal of the selected bitline to be output to the data line.

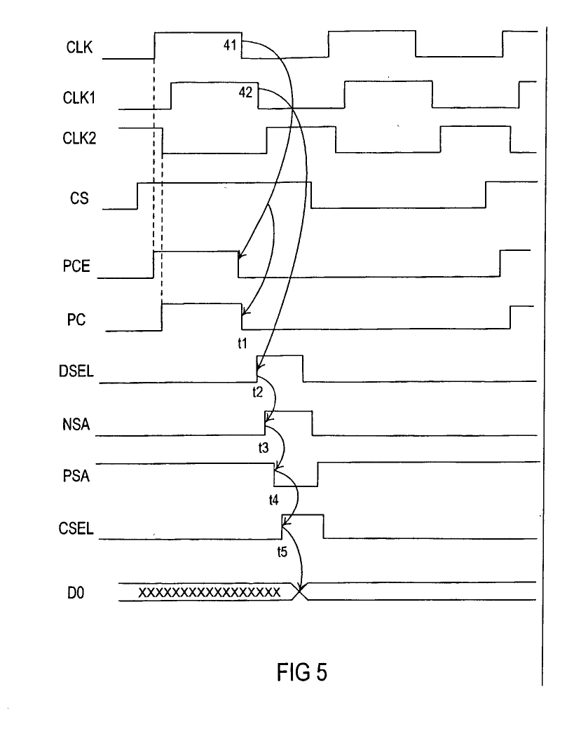

FIG. 5 shows the timing diagram of a read access in accordance with one embodiment of the invention. As shown, a system clock signal CLK is supplied to the memory device. In one embodiment, first and second clock signals CLK1 and CLK2 are also provided. The first and second clock signals are, for example, derived from CLK and are non-overlapping. The clock signal CLK can be used as a time basis for the data output signals. The clock signals together can be used to drive and synchronize the internal control signals. In one embodiment, a read access is initiated with an active chip select signal CS (41) and address information (not shown). The active CS signal, as shown, is a logic 1 signal. The read access selects one or more memory cells of memory array, depending on the architecture.

When a read access is initiated, active PCE and PC signals are provided. This activates the precharge portion of the sense amplifier to equalize the bitlines to V_{REF}. In one embodiment, PCE is activated slightly before PC. This equalizes the bitlines prior to precharging them to V_{REF}. This can be achieved by synchronizing the active PCE signal with CLK and PC with CLK2. Activating both PC and PCE simultaneously or PCE after PC can also be useful. In response to the next falling edge 41 of the CLK signal after an active CS signal, the PCE and PC signals are deactivated, disabling the precharge portion of the sense amplifier. At this point, the bitlines are equalized to V_{REF}. The equalization of the bitlines is also maintained shortly after the switching off of the precharging portion of the sense amplifier. In an alternative embodiment, an inverted CLK signal is provided. For such applications, the PCE and PC signals can be deactivated using the rising edge of the inverted CLK signal after an active CS signal.

A wordline is coupled to the decoder by activating the DSEL signal. The DSEL signal, for example, is synchronized with the falling edge 42 of CLK1. Alternatively an active DSEL signal is provided in response to the falling edge of PCE. The decoder activates the dummy cell on the non-selected bitlines (e.g., if the selected wordline couples memory cells to BL1, then decoder couples dummy cells to BL2). Through the use of dummy cells, both input terminals of the sense amplifier of a column are subjected to the same capacitance.

The selected wordline is driven to, for example, a logic 1 level. The storage capacitor in the selected cell is coupled to its respective bitline and outputs its charge onto the bitline. The charge of the selected capacitor causes a differential read signal on the bitlines of column. For example, if the capacitor comprises a positive charge indicative of, for example, a logical “1”, the potential of selected bitline is shifted slightly positive compared to equalization level V_{REF}. As such the differential read signal is positive. On the other hand, if the cell stores a logical 0, the differential read signal is negative.

In one embodiment, an active NSA signal is provided to switch on the n-channel-transistors portion of the sense amplifier shortly after the activation of the decoder select signal DSEL. For example, the NSA signal is activated in response to an active DSEL signal. Depending on whether the differential signal is positive or negative, the reference or selected bitline is amplified to a logic 0 or ground potential V_{SS}. For example, the bitline of a column having the lower potential is amplified to V_{SS}.

In accordance with one embodiment of the invention, the p-channel portion of sense amplifier is activated after the activation of the n-channel portion. For example, the PSA signal is activated in response to the active NSA signal, thus providing a delay between the activation of the n-channel portion and p-channel portion. The active PSA signal enables the p-channel-transistor portion of sense amplifier to charge the bitline with the higher potential. Both amplifier portions amplify the signals on the bitlines of the columns to their respective voltage levels. The amplification ends when the potentials V_{SS} for a low level and V_{DD} for a high level are reached. Subsequently, an active column select signal CSEL is provided and outputs the amplified signal on the selected bitline onto the internal data bus. An output driver, for example, then drives the output signal onto an output pin.

In accordance with one embodiment of the invention, the n-channel transistor portion of the sense amplifier, which drives the low level of the bitline signals on the bitline pair of the column, is activated before the p-channel transistor section of the sense amplifier, which drives the high level of the bitline signals, is activated. As a result, the magnitude of the differential signal on the bitline pair when the p-channel portion is activated is larger than the initial potential difference 51. The two-step amplification operation is more reliable, and the probability of signal distortion by signal spikes is decreased. Further, the power consumption generated by the amplification process for the n-channel-transistor portion and the p-channel-transistor portion is split to two different time instances. The peak power consumption is reduced. Although the preferred embodiment of the invention is to switch the n-channel portion before the p-channel portion of the sense amplifier, it is also useful to switch the p-channel portion before the n-channel portion and start the amplification operation for the high level signal before the amplification operation of the low level signal.

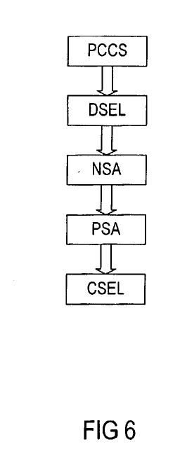

The sequence of control signals PC, CS, DSEL, NSA, PSA, CSEL as described above is again shown in FIG. 6. The same sequence can also be used during a write operation when data provided at an input terminal of the memory device is written into a selected one of the memory cells. In case of a write operation, the column select signal CSEL is activated concurrently with the decoder select signal DSEL.

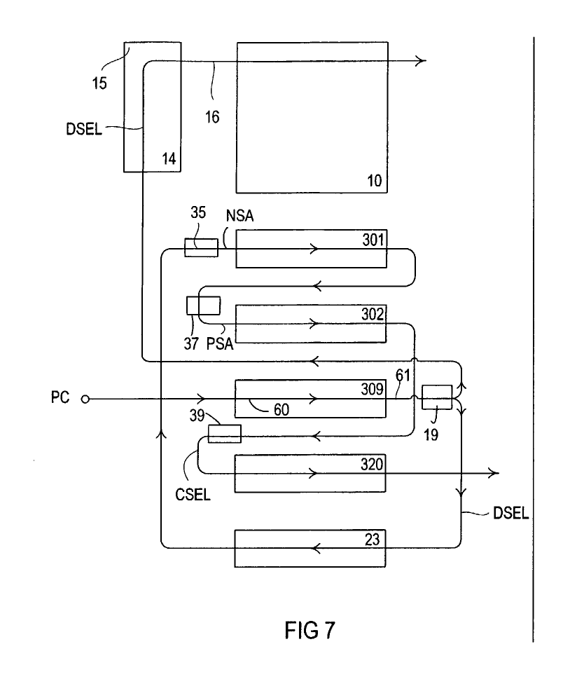

FIG. 7 shows how the sequence of control signals are generated in accordance with one embodiment of the invention. The rising and falling edges of the control signals PC, DSEL, NSA, PSA, CSEL, are generated from two clock signals derived from the system clock signal CLK by a delay circuit. The delay circuit, in one embodiment, can be implemented with the use of propagation delay. Additional delay elements, such as buffers, can also be used, if necessary. The respective clock signals are bi-phase non-overlapping clock signals CLK1, CLK2 as shown in FIG. 5.

The precharge control signals PC, PCE are deactivated with the falling edge of clock signal CLK or the rising edge of clock signal CLK2. The precharge signal PC or PCE is input into a delay line 60. It is to be noted that due to the column arrangement of memory cells, sense amplifiers and transmission gates, the respective elements can be arranged in the form of banks. The PC signal propagates along a line 60 through the bank of precharge amplifiers 309 and activates or deactivates the precharge portion of the leftmost sense amplifier prior to a precharge portion of any other sense amplifier to its right-hand side. The signal obtained at the output 61 of the precharge amplifier bank 309 is used to provide the decoder select signal DSEL via the gating device 19 coupled to the row decoder 15 and also to the dummy cell devices 23. Next, the signal DSEL, after propagating through the dummy cell bank 23, is input to the gating device 35, to provide a control signal NSA to the bank of n-channel-transistor portions 301 of the sense amplifiers.

After propagating the signal NSA through the bank 301, it is input to a gating device 37 to provide a signal PSA to the p-channel-transistor portion 302 of the sense amplifiers. As a result, the last n-channel-transistor portion of the sense amplifiers, which is located at the right-hand end of bank 301, is activated before the first p-channel portion, which is located at the left-hand end of bank 302, is activated. Finally, the control signal PSA that is output from bank 302, is input to the gating device 39 to provide the column select signal CSEL to the transmission gate bank 320.

Between the various banks, appropriate delay elements can be inserted to achieve a suitable delay between the active edges of the signals PC, DSEL, NSA, PSA, CSEL, as shown in FIGS. 3 and 4. Alternatively, variations in clock signals can be provided to ensure a suitable timing between the control signals. These techniques are well-known to a person skilled in the art.

Finally, in order to deactivate the precharge control signal PC, the rising edge of the clock signal CLK causes a high level of the signal PC. Also, the decoder select signal DSEL is deactivated by the rising edge of the clock signal CLK. The signals NSA, PSA, CSEL are deactivated at the same time upon the occurrence of a rising edge of one of the bi-phased non-overlapping clock signals, in this case clock signal CLK1.

While the invention has been particularly shown and described with reference to various embodiments, it will be recognized by those skilled in the art that modifications and changes may be made to the present invention without departing from the spirit and scope thereof. The scope of the invention should therefore be determined not with reference to the above description but with reference to the appended claims along with their full scope of equivalents.

1. A method for operating a memory device, comprising the steps of:
deactivating a precharging of a bitline and a reference bitline;
activating a wordline, thereby outputting a charge from a memory cell onto one of said bitlines;
activating a first amplification operation of a signal on one of said bitlines;
activating a second amplification operation of a signal of the other one of said bitlines; and
outputting one of said amplified signals onto a data path.

2. The method according to claim 1, wherein said first amplification operation results in a low level signal and said second amplification operation results in a high level signal.

3. The method according to claim 2, wherein said first and second amplification operations are performed by a sense amplifier, said sense amplifier having a first circuit portion comprising cross-coupled n-channel-MOS-transistors and a first switching transistor and a second circuit portion comprising cross-coupled p-channel-MOS-transistors and a second switching transistor, each switching transistor being connected to a respective supply potential, comprising the step of switching on said first switching transistor before switching on said second switching transistor.

4. The method according to claim 1, wherein said step of outputting one of said amplified signals to said data path is started by a control signal which is activated when said amplified signals exceed a respective threshold level.

5. The method according to claim 1, wherein said first amplification operation is started by a first control signal and said second amplification operation is started by a second control signal wherein a pulse of said first control signal is delayed by a delay time to generate a pulse of said second control signal.

6. The method according to claim 1, comprising:
the step of precharging said bitlines before activating a wordline and applying a potential which is the average of the fully amplified potentials on the bitlines.

7. The method according to claim 6, wherein said step of activating a wordline comprises the step of connecting a dummy cell to one of said bitlines.

8. A method according to claim 1, wherein said step of deactivating the precharging of said bitlines is performed in response to an edge of a first type of a clock signal and an active level of a memory device select signal, and wherein the precharging is activated again at the occurrence of the subsequent edge of said clock signal, said precharging is maintained constantly until the occurrence of a subsequent edge of said first type of said clock signal and an active level of said memory device select signal.

9. The method according to claim 8, wherein said first type of an edge of said clock signal is the falling edge of said clock signal.

10. A method for operating a memory device, said device comprising:
a memory cell array;
a sense amplifier coupled to at least one memory cell of said array;
said sense amplifier having an n-channel-transistor portion and a p-channel-transistor portion; wherein
the method comprises the step of:
during a read operation or a write operation to be performed on at least one memory cell, enabling said n-channel-transistor portion of said sense amplifier and then enabling said p-channel-transistor portion of said sense amplifier.

11. The method according to claim 10, comprising the step of:
generating a pulse of a first control signal enabling said n-channel-transistor portion, propagating said pulse through a delay and generating a pulse of a second control signal enabling said p-channel-transistor portion after the expiration of said delay.

12. The method according to claim 11, wherein said memory device comprises a row of n-channel-transistor portions wherein said pulse of said first control signal enabling said n-channel-transistor portion propagates through said row of n-channel-transistor portions to generate said second control signal for said p-channel-transistor portions.
